(19) United States
(12) Patent Application Publication
(10) Pub. No.: US 2008/0157307 A1
(43) Pub. Date: Jul. 3, 2008

(54) LEAD FRAME

(75) Inventor: Tsing Chow WANG, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: SEMICONDUCTOR MANUFACTURING INTERNATIONAL (Shanghai) CORPORATION, Shanghai (CN)

(21) Appl. No.: 11/833,247

(22) Filed: Aug. 3, 2007

(30) Foreign Application Priority Data
Dec. 28, 2006 (CN) 200610148240.1
Mar. 22, 2007 (CN) 200710038446.3

(51) Int. Cl. H01L 23/495

(52) U.S. Cl. 257/676; 257/E23.031

(57) ABSTRACT

A lead frame comprises a die pad and leads arranged around the die pad. Through holes are provided in the die pad, and the through holes are located in the peripheries, i.e., margin area of the die pad. The through holes serve to be passed through by the metal wires connected with the leads. By means of the above-described lead frame, the subsequent packaging process of the semiconductor chip; including dual chips and/or multi-chips assembly, is simplified and the effect of the manufacturing process is improved, at the same time, the manufacturing cost is reduced.

### TECHNICAL FIELD

The present invention relates to the field of semiconductor chip packaging, in particular to a lead frame used in the packaging process of the semiconductor chip.

### BACKGROUND ART

With the ever-increasing requirements of miniaturization, lightweight and multifunction of electronic components, the density of semiconductor packaging keeps increasing, thus the packaging dimension and the packaging area have to be reduced. In the technologies developed for fulfilling the above requirements, the semiconductor packaging technology for multi-chip plays a significant role in relation to overall cost, efficiency and reliability of chip packaging.

In the process of packaging semiconductor chip, a lead frame is required for electrically connecting a semiconductor chip with an exterior circuit so as to provide the functions performed by the semiconductor chip to the exterior circuit. Additionally, the lead frame can also physically support the semiconductor chip.

The structure of the conventional lead frame is disclosed, see for example, U.S. Pat. No. 4,289,922 granted on Sep. 15, 1981. For illustration, FIG. 1 shows a lead frame 100 of the type of Quad Flat Package (QFP) comprises a die pad 104 for mounting a semiconductor chip, and a plurality of leads 102 arranged around the die pad 104.

The conventional lead frame has a single-layer structure, which is adapted to be used in single-chip semiconductor packaging with the chip being placed on the die pad. If it is desired to form a multi-chip semiconductor packaging, the chips need to be stacked on the die pad. If the chips are placed on the different zones of the die pad, the placed orientations of the chips on two opposite zones are different. In this situation, the chip on one of the two zones need to be further rewired so as to enable the interior connecting lines of the chips on two zones to be symmetric, U.S. Pat. No. 6,674,173 granted on Jan. 6, 2004 disclosed a method of assembly stacked dual chips and/or multi-chips package with rewired substrate wafer and single layer lead frame, which increases the complication of the manufacturing process, reduces the reliability of the semiconductor packaging and increases the cost.

### DISCLOSURE OF INVENTION

The problem to be resolved by the present invention is to provide a lead frame, which can prevent the increase of the complication of the manufacture process, the reduction of the reliability of the semiconductor packaging and the increase of the cost.

In order to resolve the above problem, the present invention provides a lead frame comprising a die pad and leads arranged around the die pad. The die pad is provided with through holes at the peripheries of the die pad. Said through holes serve to be passed through by the metal wires connected with the leads.

The through holes have the shape of regular or irregular polygon.

The side lines of said polygon may be linear lines, arcuate lines or a combination of the linear and the arcuate lines.

Said through holes are closed, being not in communication with the leads; or opened, being in communication with the leads.

Said lead frame has a single-layer structure.

The material of said lead frame is metal or alloy.

Said lead frame is of the type of Quad Flat Package or Dual In-line Package.

Compared with the prior art, the present invention has the following advantages: according to the present invention, the die pad is provided with through holes located in the margin area (i.e., peripheries area) of the die pad, so that the chips mounted subsequently on the two side portions of the die pad can be placed in the same orientation; therefore, interior connecting lines of the chips on two side portions of the die pad are symmetric, which simplifies the packaging process of the semiconductor chips, improves the flexibility and the effect of the manufacturing process, and reduces the cost at the same time.

The present invention has further advantages: according to the present invention, the shapes of the through holes on the die pad are regular or irregular polygon, the shapes of the through holes can be selected depending on the actual situations, which further improves the flexibility of the manufacturing process.

### BRIEF DESCRIPTION OF THE DRAWINGS

FIG. 1 is a schematic view of the structure of a lead frame of type of Quad Flat Package according to the prior art;

FIG. 2 is a schematic view of the first structure of a lead frame of the type of Dual In-line Package according to the first embodiment of the present invention;

FIG. 3 is a schematic view of the second structure of a lead frame of the type of Dual In-line Package according to the first embodiment of the present invention;

FIG. 4 is a schematic view of the first structure of a lead frame of the type of Dual In-line Package according to the second embodiment of the present invention;

FIG. 5 is a schematic view of the second structure of a lead frame of the type of Dual In-line Package according to the second embodiment of the present invention;

FIG. 6 is a schematic view of the first structure of a lead frame of the type of Quad Flat Package according to the first embodiment of the present invention;

FIG. 7 is a schematic view of the second structure of a lead frame of the type of Quad Flat Package according to the first embodiment of the present invention;

FIG. 8 is a schematic view of the first structure of a lead frame of the type of Quad Flat Package according to the second embodiment of the present invention;

FIG. 9 is a schematic view of the second structure of a lead frame of the type of Quad Flat Package according to the second embodiment of the present invention.

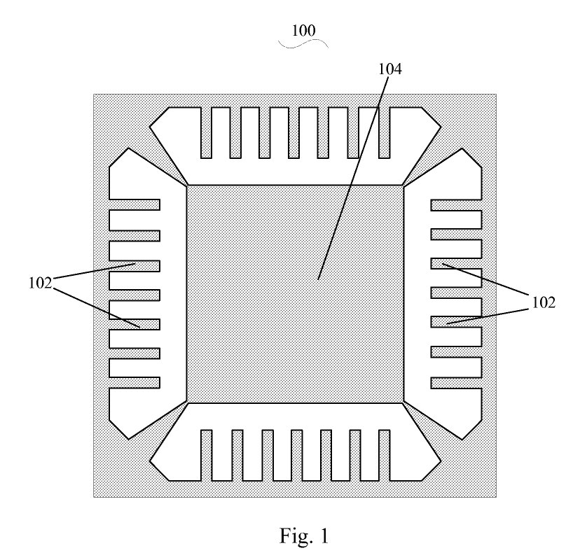

### DETAILED DESCRIPTION OF THE PREFERRED EMBODIMENTS

The die pad of the conventional lead frame is a unitary connecting body, which is adapted to be used in the single-chip semiconductor packaging with the chips being placed on the die pad. If it is desired to form a multi-chips semiconductor packaging, the chips need to be stacked on the die pad. If the chips are placed on the different area of the die pad, the placed orientations of the chips on two side areas are different. In this situation, the chip on one of the two areas need to be further rewired so as to enable the interior connecting lines of the chips on two areas to be symmetric, which increases the complication of the manufacturing process, reduces the reliability of the semiconductor packaging and increases the cost. In the present invention, the die pad is provided with the through holes at the peripheries of the die pad, so that the chips mounted subsequently on the two opposite areas of the die pad can be placed in the same orientation; therefore, the interior connecting lines of the chips on two area of the die pad are symmetric, which simplifies the packaging process of the semiconductor chip, improves the flexibility and the effect of the manufacturing process, and reduces the cost. Hereafter, the embodiments of the present invention will be described in detail with reference to the accompanying drawings.

The lead frame of the present invention comprises a die pad and leads arranged around the die pad; the die pad is provided with through holes at the margin of the die pad; said through holes serve as passages for the metal wires connected with the leads passing through.

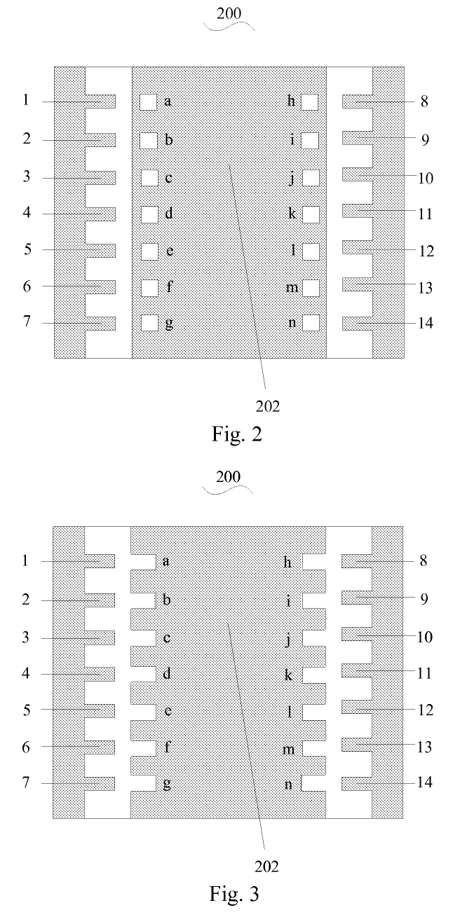

FIG. 2 is a schematic view of the first structure of a lead frame of the type of Dual In-line Package according to the first embodiment of the present invention. As shown in FIG. 2, the lead frame 200 comprises a die pad 202 and leads 1, 2, 3, 4, 5, 6, 7, 8, 9, 10, 11, 12, 13 and 14 arranged around the die pad 202, the leads 1, 2, 3, 4, 5, 6, 7, 8, 9, 10, 11, 12, 13 and 14 being extended outward and spaced from the die pad 202 in a shape of comb; the die pad 202 has closed through holes a, b, c, d, e, f, g, h, i, j, k, l, m, and n, with the same shape, and the number and the location of the closed through holes correspond to those of the leads 1, 2, 3, 4, 5, 6, 7, 8, 9, 10, 11, 12, 13 and 14, the closed through holes a, b, c, d, e, f, g, h, i, j, k, l, m, and n are located in the peripheries (i.e., margin area) of the die pad 202; wherein the closed through hole a corresponds to the lead 1, the closed through hole b corresponds to the lead 2, the closed through hole c corresponds to the lead 3, the closed through hole d corresponds to the lead 4, the closed through hole e corresponds to the lead 5, the closed through hole f corresponds to the lead 6, the closed through hole g corresponds to the lead 7, the closed through hole h corresponds to the lead 8, the closed through hole i corresponds to the lead 9, the closed through hole j corresponds to the lead 10, the closed through hole k corresponds to the lead 11, the closed through hole l corresponds to the lead 12, the closed through hole m corresponds to the lead 13, and the closed through hole n corresponds to the lead 14.

In the present embodiment, the dimensions of the closed through holes a, b, c, d, e, f, g, h, i, j, k, l, m, and n are greater than 0.2 mm×0.2 mm. In addition to the size adopted in this embodiment, the dimensions of the closed through holes a, b, c, d, e, f, g, h, i, j, k, l, m, and n can be freely selected, as long as the die pad 202 is not disconnected with the whole lead frame 200 and the die pad 202 has an area for carrying the chip.

The shapes of the closed through holes a, b, c, d, e, f, g, h, i, j, k, l, m, and n may be regular or irregular polygon, wherein the side lines of the polygon may be linear line, arcuate lines or a combination of the linear and arcuate lines. In the present embodiment, the shapes of the closed through holes a, b, c, d, e, f, g, h, i, j, k, l, m, and n are quad, specifically, square or rectangle. In addition to the embodiment, the closed through holes a, b, c, d, e, f, g, h, i, j, k, l, m, and n may be circle, semicircle, ellipse, semi-ellipse, triangle, pentagon, hexagon, heptagon, octagon, enneagon, decagon, hendecagon, dodecagon, triangle with rounded corners, quad with rounded corners, pentagon with rounded corners, hexagon with rounded corners, heptagon with rounded corners, octagon with rounded corners, enneagon with rounded corners, decagon with rounded corners, hendecagon with rounded corners, or dodecagon with rounded corners and so on. Furthermore, the shapes of the closed through holes a, b, c, d, e, f, g, h, i, j, k, l, m, and n may be different from each other. However, since the metal wires which pass through the closed through holes a, b, c, d, e, f, g, h, i, j, k, l, m, and n, and connect with the leads has circular sections, the shapes of the closed through holes a, b, c, d, e, f, g, h, i, j, k, l, m, and n are preferably circle or ellipse in order to match the shapes of the metal wires.

In the present embodiment, the material of the lead frame 200 is metal or alloy.

FIG. 3 is a schematic view of the second structure of a lead frame of the type of Dual In-line Package according to the first embodiment of the present invention. As shown in FIG. 3, the lead frame 200 comprises a die pad 202 and leads 1, 2, 3, 4, 5, 6, 7, 8, 9, 10, 11, 12, 13 and 14 arranged around the die pad 202, the leads 1, 2, 3, 4, 5, 6, 7, 8, 9, 10, 11, 12, 13 and 14 being extended outward and spaced from the die pad 202 in a comb shape; the die pad 202 in its peripheries, i.e., margin area has opened through holes a, b, c, d, e, f, g, h, i, j, k, l, m, and n with the same shape, the number and location of the opened through holes correspond to those of the leads 1, 2, 3, 4, 5, 6, 7, 8, 9, 10, 11, 12, 13 and 14, the opened through holes a, b, c, d, e, f, g, h, i, j, k, l, m, and n are located in the peripheries of the die pad 202; wherein the opened through hole a corresponds to the lead 1, the opened through hole b corresponds to the lead 2, the opened through hole c corresponds to the lead 3, the opened through hole d corresponds to the lead 4, the opened through hole e corresponds to the lead 5, the opened through hole f corresponds to the lead 6, the opened through hole g corresponds to the lead 7, the opened through hole h corresponds to the lead 8, the opened through hole i corresponds to the lead 9, the opened through hole j corresponds to the lead 10, the opened through hole k corresponds to the lead 11, the opened through hole l corresponds to the lead 12, the opened through hole m corresponds to the lead 13, and the opened through hole n corresponds to the lead 14.

In the present embodiment, the opened through holes a, b, c, d, e, f, g, h, i, j, k, l, m, and n are open in the edges of the die pad 202,being in communication with the leads 1, 2, 3, 4, 5, 6, 7, 8, 9, 10, 11, 12, 13 and 14.

The dimensions of the opened through holes a, b, c, d, e, f, g, h, i, j, k, l, m, and n are 0.2 mm×0.3 mm. In addition to the size adopted in this embodiment, the dimensions of the opened through holes a, b, c, d, e, f, g, h, i, j, k, l, m, and n can be freely selected, as long as the die pad 202 is not disconnected with the whole lead frame 200 and the die pad 202 has an area for carrying the chip.

The shapes of the opened through holes a, b, c, d, e, f, g, h, i, j, k, l, m, and n may be regular or irregular polygon, wherein the side lines of the polygon may be linear lines, arcuate lines or a combination of the linear and arcuate lines . In the present embodiment, the shapes of the opened through holes a, b, c, d, e, f, g, h, i, j, k, l, m, and n are quad, specifically, square or rectangle. In addition to the embodiment, the opened through holes a, b, c, d, e, f, g, h, i, j, k, l, m, and n may be circle, semicircle, ellipse, semi-ellipse, triangle, pentagon, hexagon, heptagon, octagon, enneagon, decagon, hendecagon, dodecagon, triangle with rounded corners, quad with rounded corners, pentagon with rounded corners, hexagon with rounded corners, heptagon with rounded corners, octagon with rounded corners, enneagon with rounded corners, decagon with rounded corners, hendecagon with rounded corners, or dodecagon with rounded corners and so on. Furthermore, the shapes of the opened through holes a, b, c, d, e, f, g, h, i, j, k, l, m, and n may be different from each other. However, since the metal wires connected with the leads through the opened through holes a, b, c, d, e, f, g, h, i, j, k, l, m, and n has circular sections, the shapes of the opened through holes a, b, c, d, e, f, g, h, i, j, k, l, m, and n are preferably semi-circle or semi-ellipse in order to match the shapes of the metal wires.

In the present embodiment, the material of the lead frame 200 is metal or alloy.

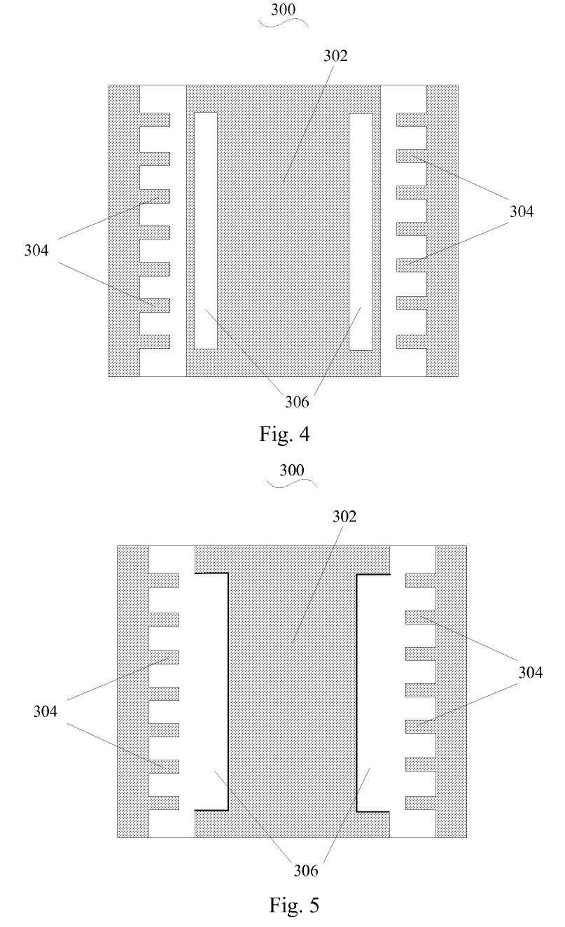

FIG. 4 is a schematic view of the first structure of a lead frame of the type of Dual In-line Package according to the second embodiment of the present invention. As shown in FIG. 4, the lead frame 300 comprises a die pad 302 and a plurality of leads 304 arranged around the die pad 302, the plurality of the leads 304 being extended outward and spaced from the die pad 302 in a comb-shape; the die pad 302 is provided with a single closed through hole 306 corresponding to each group of the leads 304, the closed through holes 306 are located in the peripheries, i.e., margin area of the die pad 302.

In the present embodiment, the dimensions of the closed through holes 306 are greater than 0.2 mm×0.2 mm. In addition to the embodiment, the dimensions of the closed through holes 306 can be freely selected, as long as the die pad 302 is not disconnected with the whole lead frame 300 and the die pad 302 has an area for carrying the chip.

The shapes of the closed through holes 306 may be regular or irregular polygon, wherein the side lines of the polygon may be linear lines, arcuate lines or a combination of the linear and arcuate lines . In the present embodiment, the shapes of the closed through holes 306 are quad, specifically, square or rectangle. In addition to the embodiment, the closed through holes 306 may be circle, semi-circle, ellipse, semi-ellipse, triangle, pentagon, hexagon, heptagon, octagon, enneagon, decagon, hendecagon, dodecagon, triangle with rounded corners, quad with rounded corners, pentagon with rounded corners, hexagon with rounded corners, heptagon with rounded corners, octagon with rounded corners, enneagon with rounded corners, decagon with rounded corners, hendecagon with rounded corners, or dodecagon with rounded corners and so on. Furthermore, the shapes of the closed through holes 306 may be different from each other. However, since the metal wires which pass through the closed through holes 306 and connect with the leads have circular sections, the shapes of the closed through holes 306 are preferably circle or ellipse in order to match the shapes of the metal wires.

In the present embodiment, the material of the lead frame 300 is metal or alloy.

FIG. 5 is a schematic view of the second structure of a lead frame of the type of Dual In-line Package according to the second embodiment of the present invention. As shown in FIG. 5, the lead frame 300 comprises a die pad 302 and a plurality of leads 304 arranged around the die pad 302, the plurality of the leads 304 being extended outward and spaced from the die pad 302 in a comb-shape; the die pad 302 has a single opened through hole 306 corresponding to each group of the leads 304, the opened through holes 306 are open in the edges of the die pad 302, being in communication with the leads 304.

In the present embodiment, the dimensions of the opened through holes 306 are greater than 0.3 mm×2 mm. In addition to the embodiment, the dimensions of the opened through holes 306 are optional, as long as the die pad 302 is not disconnected with the whole lead frame 300 and the die pad 302 has an area for carrying the chip.

The shapes of the opened through holes 306 may be regular or irregular polygon, wherein the side lines of the polygon may be linear lines, arcuate lines or a combination of the linear and arcuate lines. In the present embodiment, the shapes of the opened through holes 306 are quad, specifically, square or rectangle. In addition to the embodiment, the opened through holes 306 may be circle, semi-circle, ellipse, semi-ellipse, triangle, pentagon, hexagon, heptagon, octagon, enneagon, decagon, hendecagon, dodecagon, triangle with rounded corners, quad with rounded corners, pentagon with rounded corners, hexagon with rounded corners, heptagon with rounded corners, octagon with rounded corners, enneagon with rounded corners, decagon with rounded corners, hendecagon with rounded corners, or dodecagon with rounded corners and so on. Furthermore, the shapes of the opened through holes 306 may be different from each other. However, since the metal wires which pass through the opened through holes 306 and connected with the leads have circular sections, the shapes of the opened through holes 306 are preferably semi-circle or semi-ellipse in order to match the shapes of the metal wires.

In the present embodiment, the material of the lead frame 300 is metal or alloy.

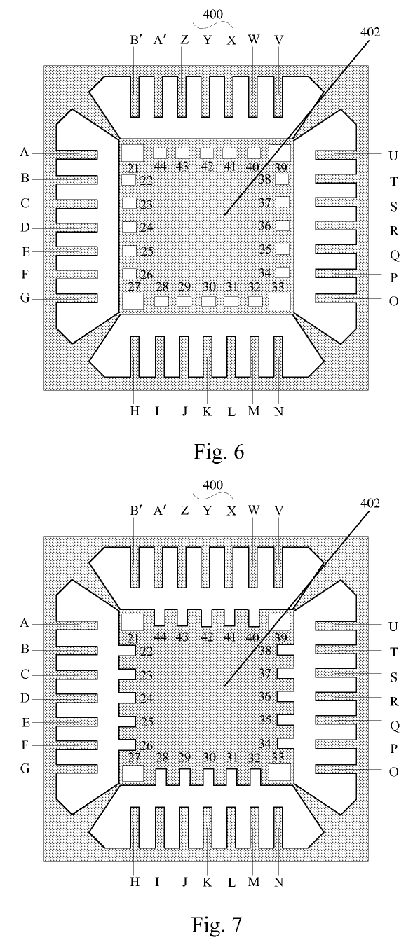

FIG. 6 is a schematic view of the first structure of a lead frame of the type of Quad Flat Package according to the first embodiment of the present invention. As shown in FIG. 6, the lead frame 400 comprises a die pad 402 and leads A, B, C, D, E, F, G, H, I, J, K, L, M, N, O, P, Q, R, S, T, U, V, W, X, Y, Z, A′ and B′ arranged around the die pad 402, the leads A, B, C, D, E, F, G, H, I, J, K, L, M, N, O, P, Q, R, S, T, U, V, W, X, Y, Z, A′ and B′ being extended outward in a comb shape and spaced from the die pad 402; the die pad 402 is provided with closed through holes 21, 22, 23, 24, 25, 26, 27, 28, 29, 30, 31, 32, 33, 34, 35, 36, 37, 38, 39, 40, 41, 42, 43 and 44 therein, which are located in the peripheries of the die pad 402; wherein the dimensions of the closed through holes 22, 23, 24, 25, 26, 28, 29, 30, 31, 32, 34, 35, 36, 37, 38, 40, 41, 42, 43 and 44 are same, and the closed through hole 22 corresponds to the lead B, the closed through hole 23 corresponds to the lead C, the closed through hole 24 corresponds to the lead D, the closed through hole 25 corresponds to the lead E, the closed through hole 26 corresponds to the lead F, the closed through hole 28 corresponds to the lead I, the closed through hole 29 corresponds to the lead J, the closed through hole 30 corresponds to the lead K, the closed through hole 31 corresponds to the lead L, the closed through hole 32 corresponds to the lead M, the closed through hole 34 corresponds to the lead P, the closed through hole 35 corresponds to the lead Q, the closed through hole 36 corresponds to the lead R, the closed through hole 37 corresponds to the lead S, the closed through hole 38 corresponds to the lead T, the closed through hole 40 corresponds to the lead W, the closed through hole 41 corresponds to the lead X, the closed through hole 42 corresponds to the lead Y, the closed through hole 43 corresponds to the lead Z, the closed through hole 44 corresponds to the lead A′, while the lead A and the lead B′ correspond to the same closed through hole 21, the lead G and the lead H correspond to the same closed through hole 27, the lead O and the lead N correspond to the same closed through hole 33, the lead U and the lead V correspond to the same closed through hole 39.

In the present embodiment, the lead A and the lead B′ share the closed though hole 21, the lead G and the lead H share the closed though hole 27, the lead O and the lead N share the closed though hole 33, the lead U and the lead V share the closed though hole 39, in order to avoid lowering the whole structural strength of the die pad 402.

In the present embodiment, the dimensions of the closed through holes 22, 23, 24, 25, 26, 28, 29, 30, 31, 32, 34, 35, 36, 37, 38, 40, 41, 42, 43 and 44 are same and greater than 0.2 mm×0.2 mm; the dimensions of the closed though holes 21, 27, 33 and 39 are same and greater than 0.4 mm×0.4 mm. In addition to the embodiment, the dimensions of the closed through holes 21, 22, 23, 24, 25, 26, 27, 28, 29, 30, 31, 32, 33, 34, 35, 36, 37, 38, 39, 40, 41, 42, 43 and 44 can be freely selected, as long as the die pad 402 is not disconnected with the whole lead frame 400 and the die pad 402 has an area for carrying the chip.

The shapes of the closed through holes 21, 22, 23, 24, 25, 26, 27, 28, 29, 30, 31, 32, 33, 34, 35, 36, 37, 38, 39, 40, 41, 42, 43 and 44 may be regular or irregular polygon, wherein the side lines of the polygon may be linear lines, arcuate lines or a combination of the linear and arcuate lines. In the present embodiment, the shapes of the closed through holes 21, 22, 23, 24, 25, 26, 27, 28, 29, 30, 31, 32, 33, 34, 35, 36, 37, 38, 39, 40, 41, 42, 43 and 44 may be quad, specifically, square or rectangle. In addition to the embodiment, the closed through holes 21, 22, 23, 24, 25, 26, 27, 28, 29, 30, 31, 32, 33, 34, 35, 36, 37, 38, 39, 40, 41, 42, 43 and 44 may also be circle, semi-circle, ellipse, semi-ellipse, triangle, pentagon, hexagon, heptagon, octagon, enneagon, decagon, hendecagon, dodecagon, triangle with rounded corners, quad with rounded corners, pentagon with rounded corners, hexagon with rounded corners, heptagon with rounded corners, octagon with rounded corners, enneagon with rounded corners, decagon with rounded corners, hendecagon with rounded corners, or dodecagon with rounded corners and so on. Furthermore, the shapes of the closed through holes 21, 22, 23, 24, 25, 26, 27, 28, 29, 30, 31, 32, 33, 34, 35, 36, 37, 38, 39, 40, 41, 42, 43 and 44 may be different from each other. However, since the metal wires passing through the closed through holes 21, 22, 23, 24, 25, 26, 27, 28, 29, 30, 31, 32, 33, 34, 35, 36, 37, 38, 39, 40, 41, 42, 43 and 44 and connected with the leads have circular sections, the shapes of the closed through holes 21, 22, 23, 24, 25, 26, 27, 28, 29, 30, 31, 32, 33, 34, 35, 36, 37, 38, 39, 40, 41, 42, 43 and 44 are preferably circle or ellipse in order to match the shapes of the metal wires.

In the present embodiment, the material of the lead frame 400 is metal or alloy.

FIG. 7 is a schematic view of the second structure of a lead frame of the type of Quad Flat Package according to the first embodiment of the present invention. As shown in FIG. 7, the lead frame 400 comprises a die pad 402 and leads A, B, C, D, E, F, G, H, I, J, K, L, M, N, O, P, Q, R, S, T, U, V, W, X, Y, Z, A′ and B′ arranged around the die pad 402, the leads A, B, C, D, E, F, G, H, I, J, K, L, M, N, O, P, Q, R, S, T, U, V, W, X, Y, Z, A′ and B′ being extended outward in a comb shape and spaced from the die pad 402; the die pad 402 is provided with opened through holes 22, 23, 24, 25, 26, 28, 29, 30, 31, 32, 34, 35, 36, 37, 38, 40, 41, 42, 43 and 44 as well as closed through holes 21, 27, 33 and 39, the opened through holes 22, 23, 24, 25, 26, 28, 29, 30, 31, 32, 34, 35, 36, 37, 38, 40, 41, 42, 43 and 44 are open in the edges of the die pad 402, being in communication with the corresponding leads; wherein the dimensions of the opened through holes 22, 23, 24, 25, 26, 28, 29, 30, 31, 32, 34, 35, 36, 37, 38, 40, 41, 42, 43 and 44 are same, and the opened through hole 22 corresponds to the lead B, the opened through hole 23 corresponds to the lead C, the opened through hole 24 corresponds to the lead D, the opened through hole 25 corresponds to the lead E, the opened through hole 26 corresponds to the lead F, the opened through hole 28 corresponds to the lead I, the opened through hole 29 corresponds to the lead J, the opened through hole 30 corresponds to the lead K, the opened through hole 31 corresponds to the lead L, the opened through hole 32 corresponds to the lead M, the opened through hole 34 corresponds to the lead P, the opened through hole 35 corresponds to the lead Q, the opened through hole 36 corresponds to the lead R, the opened through hole 37 corresponds to the lead S, the opened through hole 38 corresponds to the lead T, the opened through hole 40 corresponds to the lead W, the opened through hole 41 corresponds to the lead X, the opened through hole 42 corresponds to the lead Y, the opened through hole 43 corresponds to the lead Z, the opened through hole 44 corresponds to the lead A′, while the lead A and the lead B′ correspond to the same closed through hole 21, the lead G and the lead H correspond to the same closed through hole 27, the lead O and the lead N correspond to the same closed through hole 33, the lead U and the lead V correspond to the same closed through hole 39.

In the present embodiment, the lead A and the lead B′ share the closed though hole 21, the lead G and the lead H share the closed though hole 27, the lead O and the lead N share the closed though hole 33, the lead U and the lead V share the closed though hole 39, in order to avoid lowering the whole structural strength of the die pad 402.

In the present embodiment, the dimensions of the opened through holes 22, 23, 24, 25, 26, 28, 29, 30, 31, 32, 34, 35, 36, 37, 38, 40, 41, 42, 43 and 44 are same in 0.2 mm×0.3 mm; the dimensions of the closed though holes 21, 27, 33 and 39 are same in 0.4 mm×0.4 mm. In addition to the embodiment, the dimensions of the opened through holes 22, 23, 24, 25, 26, 28, 29, 30, 31, 32, 34, 35, 36, 37, 38, 40, 41, 42, 43, 44 and the closed through holes 21, 27, 33 and 39 can be optionally selected, as long as that the die pad 402 is not disconnected with the whole lead frame 400 and the die pad 402 has an area for carrying the chip.

The shapes of the opened through holes 22, 23, 24, 25, 26, 28, 29, 30, 31, 32, 34, 35, 36, 37, 38, 40, 41, 42, 43, 44 and the closed through holes 21, 27, 33 and 39 may be regular or irregular polygon, wherein the side lines of the polygon may be linear lines, arcuate lines or a combination of the linear and arcuate line. In the present embodiment, the shapes of the opened through holes 22, 23, 24, 25, 26, 28, 29, 30, 31, 32, 34, 35, 36, 37, 38, 40, 41, 42, 43, 44 and the closed through holes 21, 27, 33 and 39 are quad, specifically, square or rectangle. In addition to the embodiment, the shapes of the opened through holes 22, 23, 24, 25, 26, 28, 29, 30, 31, 32, 34, 35, 36, 37, 38, 40, 41, 42, 43, 44 and the closed through holes 21, 27, 33 and 39 may also be circle, semi-circle, ellipse, semi-ellipse, triangle, pentagon, hexagon, heptagon, octagon, enneagon, decagon, hendecagon, dodecagon, triangle with rounded corners, quad with rounded corners, pentagon with rounded corners, hexagon with rounded corners, heptagon with rounded corners, octagon with rounded corners, enneagon with rounded corners, decagon with rounded corners, hendecagon with rounded corners, or dodecagon with rounded corners and so on. Furthermore, the shapes of the opened through holes 22, 23, 24, 25, 26, 28, 29, 30, 31, 32, 34, 35, 36, 37, 38, 40, 41, 42, 43, 44 and the closed through holes 21, 27, 33 and 39 may be different from each other. However, since the metal wires connected with the leads and passing through the opened through holes 22, 23, 24, 25, 26, 28, 29, 30, 31, 32, 34, 35, 36, 37, 38, 40, 41, 42, 43, 44 and the closed through holes 21, 27, 33 and 39 have circular sections, the shapes of the opened through holes 22, 23, 24, 25, 26, 28, 29, 30, 31, 32, 34, 35, 36, 37, 38, 40, 41, 42, 43, 44 are preferably semi-circle or semi-ellipse as well as the shapes of the closed through holes 21, 27, 33 and 39 are preferably circle or ellipse in order to match the shapes of the metal wires.

In the present embodiment, the material of the lead frame 400 is metal or alloy.

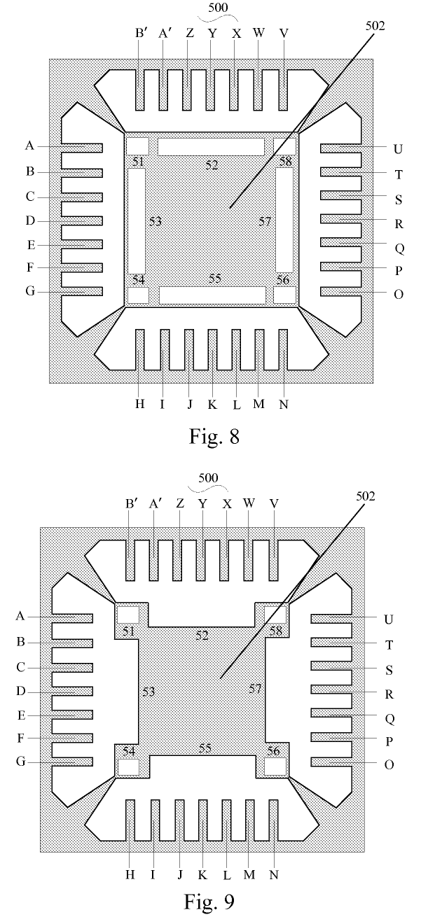

FIG. 8 is a schematic view of the first structure of a lead frame of the type of Quad Flat Package according to the second embodiment of the present invention. As shown in FIG. 8, the lead frame 500 comprises a die pad 502 and leads A, B, C, D, E, F, G, H, I, J, K, L, M, N, O, P, Q, R, S, T, U, V, W, X, Y, Z, A′ and B′ arranged around the die pad 502, the leads A, B, C, D, E, F, G, H, I, J, K, L, M, N, O, P, Q, R, S, T, U, V, W, X, Y, Z, A′ and B′ being extended outward and in a comb shape and spaced from the die pad 502; the die pad 502 is provided with closed through holes 51, 52, 53, 54, 55, 56, 57 and 58 which are located in the peripheries, i.e., margin area of the die pad 502; wherein the dimensions of the closed through holes 51, 52, 53, 54, 55, 56, 57 and 58 are same, and the leads W, X, Y, Z, A′ correspond to the same closed through holes 52, the leads B, C, D, E, F correspond to the same closed through holes 53, the leads I, J, K, L, M correspond to the same closed through holes 55, the leads P, Q, R, S, T correspond to the same closed through holes 57; the dimensions of the closed through holes 51, 54, 56, 58 are same and smaller than those of the closed through holes 52, 53, 55 and 57, wherein the lead A and the lead B′ correspond to the same closed through hole 51, the lead G and the lead H correspond to the same closed through hole 54, the lead O and the lead N correspond to the same closed through hole 56, the lead U and the lead V correspond to the same closed through hole 58.

In the present embodiment, the dimensions of the closed through holes 52, 53, 55 and 57 are same and greater than 0.2 mm×2 mm; the dimensions of the closed though holes 51, 54, 56 and 58 are same in 0.4 mm×0.4 mm. In addition to the embodiment, the dimensions of the closed through holes 51, 52, 53, 54, 55, 56, 57 and 58 can be optionally selected, as long as die pad 502 is not disconnected with the whole lead frame 500 and the die pad 502 has an area for carrying the chip.

The shapes of the closed through holes 51, 52, 53, 54, 55, 56, 57 and 58 may be regular or irregular polygon, wherein the side lines of the polygon may be linear lines, arcuate lines or a combination of the linear and arcuate lines. In the present embodiment, the shapes of the closed through holes 51, 52, 53, 54, 55, 56, 57 and 58 are quad, specifically, square or rectangle. In addition to the embodiment, the closed through holes 51, 52, 53, 54, 55, 56, 57 and 58 may also be circle, semi-circle, ellipse, semi-ellipse, triangle, pentagon, hexagon, heptagon, octagon, enneagon, decagon, hendecagon, dodecagon, triangle with rounded corners, quad with rounded corners, pentagon with rounded corners, hexagon with rounded corners, heptagon with rounded corners, octagon with rounded corners, enneagon with rounded corners, decagon with rounded corners, hendecagon with rounded corners, or dodecagon with rounded corners and so on. Furthermore, the shapes of the closed through holes 51, 52, 53, 54, 55, 56, 57 and 58 may be different from each other. However, since the metal wires connected with the leads and passing through the closed through holes 51, 52, 53, 54, 55, 56, 57 and 58 have circular sections, the shapes of the closed through holes 51, 52, 53, 54, 55, 56, 57 and 58 are preferably circle or ellipse in order to match the shapes of the metal wires.

In the present embodiment, the material of the lead frame 500 is metal or alloy.

FIG. 9 is a schematic view of the second structure of a lead frame of the type of Quad Flat Package according to the second embodiment of the present invention. As shown in FIG. 9, the lead frame 500 comprises a die pad 502 and leads A, B, C, D, E, F, G, H, I, J, K, L, M, N, O, P, Q, R, S, T, U, V, W, X, Y, Z, A′ and B′ arranged around the die pad 502, the leads A, B, C, D, E, F, G, H, I, J, K, L, M, N, O, P, Q, R, S, T, U, V, W, X, Y, Z, A′ and B′ being extended outward and in a comb shape and spaced from the die pad 502; the die pad 502 is provided with opened through holes 52, 53, 55, 57 in the same dimension as well as closed through holes 51, 54, 56 and 58 in the same dimension which is smaller than those of the opened through holes 52, 53, 55, 57, the opened through holes 52, 53, 55, 57 are open in the edges of the die pad 502, being in communication with the corresponding leads; wherein the leads W, X, Y, Z, A′ correspond to the same opened through holes 52, the leads B, C, D, E, F correspond to the same opened through holes 53, the leads I, J, K, L, M correspond to the same opened through holes 55, the leads P, Q, R, S, T correspond to the same opened through holes 57; the lead A and the lead B′ correspond to the same closed through hole 51, the lead G and the lead H correspond to the same closed through hole 54, the lead O and the N correspond to the same closed through hole 56, the lead U and the V correspond to the same closed through hole 58.

In the present embodiment, the dimensions of the opened through holes 52, 53, 55 and 57 are same and greater than 0.3 mm×2 mm; the dimensions of the closed though holes 51, 54, 56 and 58 are same in 0.4 mm×0.4 mm. In addition to the embodiment, the dimensions of the opened through holes 52, 53, 55, 57 and the closed through holes 51, 54, 56 and 58 can be optionally selected such that the die pad 502 is not disconnected with the whole lead frame 500 and the die pad 502 has an area for carrying the chip.

The shapes of the opened through holes 52, 53, 55, 57 and the closed through holes 51, 54, 56 and 58 may be regular or irregular polygon, wherein the side lines of the polygon may be linear lines, arcuate lines or a combination of the linear and arcuate lines. In the present embodiment, the shapes of the opened through holes 52, 53, 55, 57 and the closed through holes 51, 54, 56 and 58 are quad, specifically, square or rectangle. In addition to the embodiment, the opened through holes 52, 53, 55, 57 and the closed through holes 51, 54, 56 and 58 may also be circle, semi-circle, ellipse, semi-ellipse, triangle, pentagon, hexagon, heptagon, octagon, enneagon, decagon, hendecagon, dodecagon, triangle with rounded corners, quad with rounded corners, pentagon with rounded corners, hexagon with rounded corners, heptagon with rounded corners, octagon with rounded corners, enneagon with rounded corners, decagon with rounded corners, hendecagon with rounded corners, or dodecagon with rounded corners and so on. Furthermore, the shapes of the opened through holes 52, 53, 55, 57 and the closed through holes 51, 54, 56 and 58 may be different from each other. However, since the metal wires connected with the leads and passing through the opened through holes 52, 53, 55, 57 and the closed through holes 51, 54, 56 and 58 have circular sections, the shapes of the opened through holes 52, 53, 55, 57 are preferably semi-circle or semi-ellipse as well as the shapes of the closed through holes 51, 54, 56 and 58 are preferably circle or ellipse in order to match the shapes of the metal wires.

In the present embodiment, the material of the lead frame 500 is metal or alloy. Furthermore, the lead frame can also be of the type of Leadless Chip Carrier Package, the type of Single Inline Package, or the type of SD Memory Card Package.

Although the invention has been disclosed with reference to preferred embodiments thereof, many possible changes and modifications of the invention may become apparent to those skilled in the art without departing from the spirit and scopes of the invention. Therefore, the protection scopes of the present invention are only limited by what defined in the claims.

1. A lead frame comprising:
a die pad; and
leads arranged around the die pad,
wherein said die pad includes through holes on the peripheries thereof, which through holes are used for metal wires connected with the leads to pass through.

2. A lead frame according to claim 1, wherein the through holes have the shape of a regular or irregular polygon.

3. A lead frame according to claim 2, wherein the side lines of said polygon are linear lines, arcuate lines or a combination of the linear and the arcuate lines.

4. A lead frame according to claim 3, wherein said through holes are closed, being not in communication with the leads.

5. A lead frame according to claim 3, wherein said through holes are opened, being in communication with the leads.

6. A lead frame according to claim 1, wherein said lead frame has a single-layer structure.

7. A lead frame according to claim 5, wherein said lead frame includes metal or alloy.

8. A lead frame according to claim 6, wherein said lead frame is of the type of Dual In-line Package.

9. A lead frame according to claim 6, wherein said lead frame is of the type of Quad Flat Package.

10. A lead frame according to claim 6, wherein said lead frame is of the type of Leadless Chip Carrier Package.

11. A lead frame according to claim 6, wherein said lead frame is of the type of Single Inline Package.

12. A lead frame according to claim 6, wherein said lead frame is of the type of SD Memory Card Package.
